(19) United States
(12) Patent Application Publication
(10) Pub. No.: US 2005/0181210 A1
(43) Pub. Date: Aug. 18, 2005

(54) Diamond structure separation

(76) Inventors: Patrick J. Doering, Holliston, MA (US); Alfred Genis, Douglas, MA (US); Robert C. Linares, Framingham, MA (US)

Correspondence Address: INTELLECTUAL PROPERTY GROUP;FREDRIKSON & BYRON, P.A., 200 SOUTH SIXTH STREET, SUITE 4000, MINNEAPOLIS, MN, 55402, US

(21) Appl. No.: 11/056,338

(22) Filed: Feb. 11, 2005

Related U.S. Application Data
(60) Provisional application No. 60/544,733, filed on Feb. 13, 2004.

(51) Int. Cl. B32B 9/00; C23C 16/00

(52) U.S. Cl. 428/408; 427/523

(57) ABSTRACT

The present invention provides a method and composition used for separating a synthetic diamond from its substrate, involving the use of ion implantation to implant ions/atoms within a diamond substrate, followed by growth of synthetic diamond on the implanted surface, and finally separation of the grown diamond, together with a portion of the implanted substrate surface, by heating in a non-oxidizing environment. The resulting composite structure can be used as is, or can be further processed, as by removing the substrate portion from the grown diamond.

### CROSS REFERENCE TO RELATED APPLICATIONS

The present application claims priority to provisional U.S. patent application filed Feb. 13, 2004 and assigned Ser. No. 60/544,733, the entire disclosure of which is incorporated herein by reference.

### TECHNICAL FIELD

The present invention relates to the process of separating synthetic diamond from a substrate that the synthetic diamond is grown upon.

### BACKGROUND OF THE INVENTION

Diamond provides a wide and useful range of properties, including extreme mechanical hardness, low coefficient of thermal expansion, high chemical inertness and wear resistance, low friction, and high thermal conductivity. Generally, diamond is also electrically insulating and optically transparent from the ultra-violet (UV) to the far infrared (IR), with the only absorption occurring from carbon-carbon bands that range from about 2.5 μm to 6 μm. Given its properties, diamond can be utilized in many diverse applications in industries involving semiconductor, optical, industrial, electrochemical, as well as gem technology; however, its overall utilization has long been hampered by the comparative scarcity of natural diamond. In turn, there has been a long-running quest for processes to synthesize diamond in the laboratory.

Synthetic diamonds are currently produced by a variety of methods. One such method involves a process referred to as chemical vapor deposition (CVD). CVD diamond has only been commercially synthesized for the last fifteen to twenty years. This diamond growing method involves providing a hydrocarbon gas (typically methane) in an excess of atomic hydrogen. Generally, a gas-phase chemical reaction occurs above a solid surface, which causes deposition onto that surface. Conventional CVD techniques for producing diamond films require a means of activating the gas-phase carbon-containing precursor molecules. This generally involves thermal (e.g., hot filament) or plasma (e.g., D.C., R.F., or microwave) activation, or the use of a combustion flame (oxyacetylene or plasma torches). Exemplary methods of such thermal and plasma activation types include the use of a hot filament reactor and the use of a microwave plasma enhanced reactor, respectively. While each method differs in regards to activation, they typically share similar aspects otherwise. For example, growth of CVD diamond (rather than deposition of other, less well-defined, forms of carbon) normally requires that the substrate be maintained at a temperature in the range of 800° C.-1400° C., and that the precursor gas be diluted in an excess of hydrogen (typical CH₄ mixing ratio ˜1%-12% in volume).

CVD diamond can be made to grow in a two- or three-dimensional manner, and therefore, it is possible to build up a bulk diamond crystal (or plate or film) of a single composition or composed of layers of many compositions. The grown diamond can have a variety of crystallographic configurations. The diamond may include many small, randomly oriented crystals (polycrystalline diamond). Alternately, the diamond may consist of numerous small crystals which are preferentially aligned in a certain crystallographic direction (commonly known as highly oriented diamond). Both polycrystalline diamond and highly oriented diamond are typically grown using a non-diamond substrate, such as silicon or molybdenum. By selection of other suitable substrates (such as Iridium), diamonds can be grown which are single crystal (over small areas) or nearly single crystal (as determined by x-ray diffraction measurements). Such diamonds are commonly known as heteroepitaxial diamond.

In other applications, the substrate, from which the CVD diamond is grown, involves a diamond seed. A diamond seed used for such purposes can involve one of a variety of diamond types, such as those prepared by “high pressure, high temperature” (HPHT) or CVD, or natural diamond. Generally, any one of these diamond seeds can be used to grow CVD diamond. Because of the high cost of diamond seed crystals however, the economics of the growth process require that a seed crystal be reused or that the grown diamond be converted into one or more seeds. This conversion process usually requires “separation” of the grown CVD diamond from the seed. The economics of the process also require one to limit the loss of diamond (“kerf loss”) during the separation process. In most current processes, this loss goes up exponentially with seed diameter for reasons which will be discussed below.

Current separation techniques include the use of conventional abrasive or laser cutting methods, however, both techniques tend to waste a significant amount of the grown CVD diamond. In abrasive cutting, a metal wheel is charged with diamond powder and rotated at high speed (generally 4,000 rpm to 5,000 rpm) in order to cut through the diamond. This process is generally slow, has a high kerf loss (due to the width of the saw blade), and produces a great deal of heat which limits yield and further decreases cutting speed. The cutting speed and kerf loss are generally dependent on the size of the diamond area to be cut. Consequently, when large diamonds are cut with such diamond impregnated cutting wheel, the sawing speed is reduced because of the increased level of heat generated from cutting such large areas. In turn, the cutting process takes longer and involves a greater amount of kerf loss. In laser cutting, the diamond surface is ablated by using high power pulsed lasers. The cutting speed is much higher (10 to 20 times) than conventional sawing, however, the kerf loss also goes up linearly as the diameter of the piece being cut increases. This occurs because the laser beam is required to have a conical shape, which generally leads to significant losses as seed diameters are increased beyond 5 mm. Thus, when choosing between these cutting methods, one has to balance the time demands for cutting against the amount of valuable diamond material potentially wasted.

Other separation techniques involve creating a graphitic layer between the substrate and grown diamond and subsequently dissolving the layer via oxidation to cause separation therebetween. As such, a graphitic layer is initially created at the substrate surface (i.e., diamond seed surface) via ion implantation, typically using carbon or oxygen atoms. Subsequently, a CVD diamond is grown on the graphitic layer (or implanted surface). Following the growth process, the graphitic layer can be dissolved by using some form of oxidation, thereby separating the grown diamond from the substrate. Oxidation methods could include heating in an oxidizing atmosphere (600° C. to 900° C.), dissolving in an oxidizing mineral acid, or dissolving by electrolysis of water. All of these methods have been successfully used in separating CVD diamond from a seed crystal when small seeds are used (e.g., 1 mm² to 5 mm²). However, the method often does not result in a complete separation, leaving behind areas of non-separated seed and grown crystal after process is completed. Additionally, in using this process, the removal rate is proportional to the base area of the diamond being removed. As such, it typically takes about 24 hours to remove a diamond having dimensions of 3 mm square (9 mM² base area) by electrolysis. Further, it takes about sixty-six times longer to remove a diamond having dimensions of 25 mm square (625 mm² base area). Finally, in removing a diameter having dimensions of 100 mm square (10000 mm² base area), a size generally required for high volume circuit production, the separation time increases by a further factor of sixteen. Thus, while this method provides significant economic improvement over abrasive and laser sawing because of reduced kerf loss, there is still a need for an economical process that can be used when very large diamond seeds are being grown, because of the less than complete separation achieved and the extended length of the process.

With recent developments in the growth and fabrication of single crystal CVD diamond, there has been much excitement in the industry in regard to CVD diamond utilization. However, without more effective techniques for separating the grown diamonds from their substrates, shortcomings will continue to exist in terms of grown diamond yield and process duration.

### SUMMARY OF THE INVENTION

The present invention provides a method and corresponding compositions for providing a synthetic diamond structure. In one preferred embodiment, the method includes providing a diamond growth substrate having a diamond growth surface with a predetermined geometry. Ion implantation is employed to deliver one or more atomic species into and beneath the diamond growth surface in order to form an implanted layer with a peak concentration of atoms at a predetermined depth beneath the diamond growth surface. A synthetic diamond of one or more diamond layers is grown upon the diamond growth surface in order to provide a composition comprising the grown synthetic diamond upon the diamond growth surface of the substrate. The composition is heated in a non-oxidizing environment under suitable conditions to cause separation of a synthetic diamond structure that includes the grown synthetic diamond together with the substrate to the predetermined depth from the remaining substrate.

The invention further provides a substrate structure having an ion implanted layer, sufficient to be used in the synthesis and removal of diamond in the manner described herein. In yet other aspects, the invention provides a synthetic diamond structure prepared by the method of this invention, and in turn, a synthetic diamond derived from the method of the invention.

Applicant has discovered, inter alia, the manner in which the preparation of an implanted ion layer, having a peak concentration of atoms at a predetermined substrate depth, can be subjected to appropriate conditions (e.g., of heat in a non-oxidizing environment) in order to predictably, consistently, and cost-effectively remove the grown diamond, taking with it substrate to the predetermined depth. The attached substrate, in turn, can be permitted to remain in place, if non-interfering with the intended use of the diamond, or can itself be removed by suitable means.

In addition to the appropriate temperatures and the non-oxidizing environment used to facilitate separation in the inventive process, both the selection and conditions of using the implanted species itself can determine and affect both the separation of the synthetic diamond structure from the remaining substrate, and in turn, the quality of the synthetic diamond itself. Given the present teaching, those skilled in the art will appreciate the manner in which various parameters concerning the implanted species can be considered, including particularly species type, species dose quantity, species energy level, and species dose rate.

The method of this invention provides various other benefits as well, including the ability to re-use the substrate, since the amount of substrate removed with the grown diamond will tend to be minimal compared to its overall size. In addition, the substrate can be modified and/or provided in varying configurations, so as to adjust the effective surface area being implanted, and in turn, increase potential for diamond yield.

### BRIEF DESCRIPTION OF THE DRAWING HAVING MULTIPLE FIGURES

FIG. 1 is a schematic elevation view of a substrate during an initial phase of ion implantation in accordance with certain embodiments of the invention;

FIG. 2 is a schematic elevation view of the substrate of FIG. 1 during a final phase of ion implantation in accordance with certain embodiments of the invention;

FIGS. 3a through 3e are graphs illustrating data computed from TRIM calculations;

FIG. 4 is a schematic elevation view of the substrate of FIG. 2 showing a synthetic diamond having been grown on the substrate in accordance with certain embodiments of the invention;

FIG. 5 is a schematic elevation view of substrate and synthetic diamond of FIG. 4 showing substrate and synthetic diamond of FIG. 4 subsequent to portions of the synthetic diamond being removed in accordance with certain embodiments of the invention;

FIG. 6 is a schematic elevation view of the substrate and synthetic diamond structure of FIG. 5 showing separation of the synthetic diamond from the substrate in accordance with certain embodiments of the invention;

FIG. 7 is a schematic elevation view of another substrate in accordance with certain embodiments of the invention;

FIG. 8 is a schematic elevation view of the substrate of FIG. 7 following ion implantation in accordance with certain embodiments of the invention;

FIG. 9 is a schematic elevation view of the substrate of FIG. 8 showing a synthetic diamond having been grown on the substrate in accordance with certain embodiments of the invention;

FIG. 10 is a schematic elevation view of the substrate and synthetic diamond structure of FIG. 9 showing separation of the synthetic diamond from the substrate in accordance with certain embodiments of the invention; and

FIG. 11 is a schematic elevation view of the respective substrates of FIGS. 2 and 8.

### DETAILED DESCRIPTION

The following detailed description is to be read with reference to the drawing, in which like elements in different figures have like reference numerals. The figures, although not to scale, depict selected embodiments, but are not intended to limit the scope of the invention. It will be understood that many of the specific details of the invention incorporated in the figures can be changed or modified by one of ordinary skill in the art without departing significantly from the spirit of the invention. While the method of invention is generally described as involving preferred stages, particularly ion implantation, followed by diamond growth, and finally separation, as further demonstrated when discussing certain embodiments of the invention, each of these stages can include one or more steps, and the stages and steps can themselves be provided in any suitable order or combination.

In a preferred embodiment, a suitable process of ion implantation is used to implant a certain ionized atomic species (e.g., hydrogen) within a substrate (e.g., diamond seed) to permit a synthetic diamond of one or more diamond layers (e.g., formed via chemical vapor deposition (CVD)) to be grown on the implanted surface. The resulting composite (the substrate and synthetic diamond) can be heated in a non-oxidizing atmosphere (e.g., plasma of hydrogen gas) in order to provide separation of a synthetic diamond structure (the synthetic diamond and a portion of the substrate) from the substrate remainder. Such a non-oxidizing atmosphere generally includes any atmosphere not containing a sufficient concentration of oxygen so as to be reactive through oxidation. Examples of such atmospheres include inert (e.g., helium, neon, argon, etc.) and other non-oxygen containing gases (e.g., hydrogen, nitrogen, etc.). Environments used to provide such atmospheres can include plasmas, vacuums, and the like.

In certain embodiments of the invention, various initial steps can be performed prior to or concurrent with the ion implantation stage. One such step involves choosing a substrate. When growing single crystalline CVD diamond, for instance, such substrate is preferably a diamond seed, and more preferably a single crystalline diamond seed. Suitable diamond seeds can include a variety of diamond types including those grown by HPHT or CVD processes, or natural diamond itself.

Upon selection of the substrate, at least one major surface of the substrate can be identified, and optionally prepared, for ion implantation. Collectively, such major surfaces are occasionally referred to herein as a diamond growth surface. Preparation of the diamond growth surface can include any suitable means for affecting the chemical and/or physical make-up of the surface, for instance, by polishing using conventional polishing methods. Preparation of this sort can be accomplished in advance of the ion implantation, and can be used to further improve subsequent diamond growth rate and/or quality, as well as ease of separation. Typically, ions are implanted in a manner at a set distance and even flux across the diamond growth surface, such that the configuration of the implanted species layer will itself replicate the surface profile of the substrate. In turn, any defects on an implanted surface of the substrate will typically have a corresponding influence on the implant profile, including on the configuration of the predetermined peak atomic layer. Preparation of the substrate can be important to initially remove such defects. In addition, in certain embodiments, edges of the substrate are cut away and/or finished, e.g., using a laser or polisher, respectively, so as to not adversely impact the “after-implant” growth as well. Finally, the diamond growth surfaces should be thoroughly cleaned for ion implanting, for instance, using solvents or other suitable methods known in the art.

Ion implantation is generally conducted under conditions of high vacuum, high voltage, and relatively low beam currents. As is known in the art, ion implantation typically involves the process of ionizing a species of atoms, subsequently accelerating the species in an electric field, and directing the accelerated, ionized species toward a substrate. With its rate of motion being accelerated, the species generally penetrates an outer surface of the substrate and come to rest within a zone in the substrate. The zone is within an implanted layer of the substrate. Such implanted layer is defined as generally extending from the outer surface of the substrate to the farthest penetration depth of the species within the substrate.

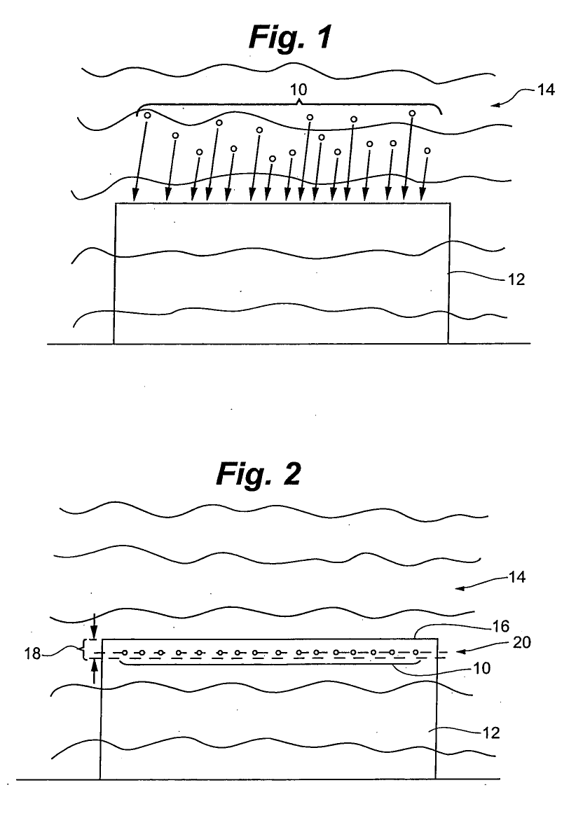

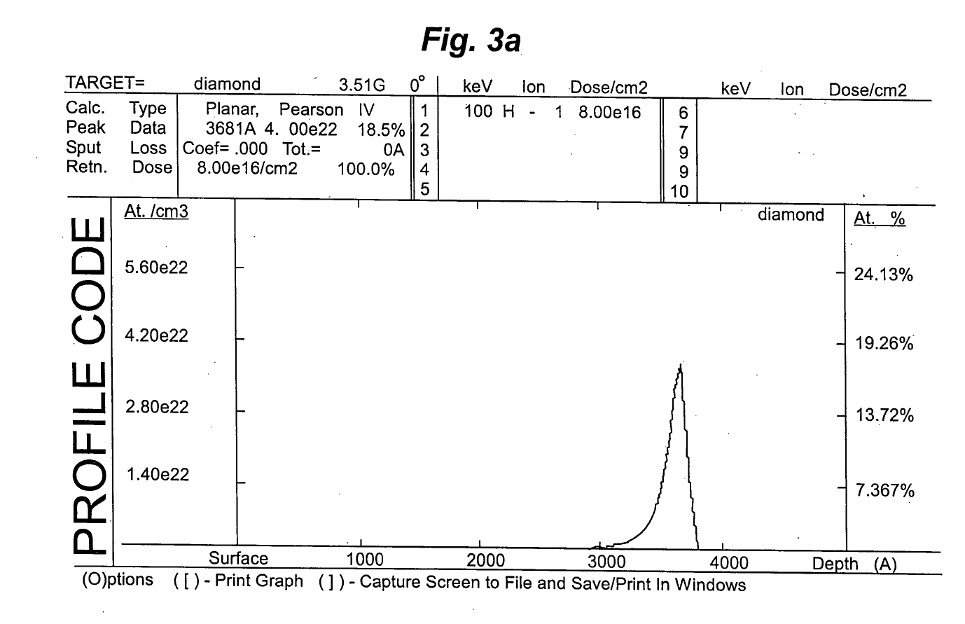

FIG. 1 shows a basic depiction of the initial phase of ion implantation, in which a desired species 10 (of ionized atoms) is accelerated toward a substrate 12 within an electric field 14. As shown, the species 10 is being accelerated toward the substrate 12 at an angle generally normal or vertical to the surface. However, the species 10 of the invention can also be accelerated toward the substrate 12 at a wide variety of angles as well. For a given species, the depth of implantation is generally accomplished with adjustments made to the electric field 14. Typically, as one increases the voltage of the electric field, the energy of the species 10 is increased, which ultimately results in a deeper implantation by the species 10 into the substrate 12. As mentioned herein, the substrate 12 is preferably a diamond seed. While the substrate 12 is shown as a rectangular shape, it is not done so with the intention of limiting the invention. It is fully contemplated that the substrate may be any of a variety of crystalline shapes. For example, the substrate may be of any predetermined geometry including a cube, cone, prism, pyramid, wedge, or other geometries, as well as frustums of each, and still be within the spirit of the invention. FIG. 2 illustrates a basic depiction of the final phase of ion implantation, in which implantation occurs at the diamond growth surface of the substrate 12, involving an upper surface 16 of the substrate 12. The species 10 generally penetrates the upper surface 16 until reaching a zone within the substrate 12. The zone is generally included within an implanted layer 18 of the substrate 12. The implanted layer 18 generally extends from the upper surface 16 of the substrate 12 to the furthest penetration depth of the species 10 within the substrate 12. A peak concentration of the species 10 is at a certain depth 20 generally known as the end of range depth. While the species 10 is only shown at the one depth 20 (the end of range depth), it should be appreciated that this is done for simplicity. Following ion implantation, the species 10 is generally distributed throughout the zone at and proximate to the end of range depth 20. As shown, the implanted layer 20 extends beneath the end of the range depth 18.

Before ion implantation is started, the species to be implanted must be selected. Many variables are considered in selecting a species, such as cost and availability, as well as concern for how much damage the species is expected to cause to the substrate lattice, as described below.

During ion implantation, by directing the species (of ionized atoms) into the crystal lattice of the substrate, the implanted portion of the lattice generally dilates or expands. Excessive dilation of the lattice in this manner generally leads to strain within the implanted layer. Consequently, excessive strain can cause damage to the implanted layer. This damage is generally represented by dislocations, or cracking, within the implanted layer. These dislocations can generally create an unfavorable outer substrate surface for growing quality synthetic diamond (e.g., producing diamond via CVD having no defects or dislocations, or insignificant amounts thereof). However, Applicants have discovered the manner in which lattice dilation can be controlled in a number of ways, and in fact, relied upon. One way involves selecting an appropriate species for implanting. In certain embodiments of the invention, hydrogen ions are implanted within a HPHT diamond seed using the conventional techniques of ion implantation. Since the covalent radius of hydrogen is small, only a small amount of lattice dilation occurs within the implanted layer. Consequently, there is little strain (and little damage) within the implanted layer. In turn, the diamond growth surface of the substrate likely provides a favorable surface for synthetic diamond growth (e.g., using CVD). Generally, as the covalent radius of the implanted species increases, the potential for creating such a favorable surface (e.g., having limited defects or dislocations) decreases.

Generally, any species can be used for ion implanting in the inventive process so long as the species is suitable for subsequently enabling separation of a portion of the implanted layer from the substrate. As such, the species is selected so as to allow for suitable implantation within the substrate. Examples of such species include most, if not all, atomic elements. In certain embodiments of the invention, the substrate is also used for growing a synthetic diamond thereon. As such, the species preferably allows for suitable implantation within the substrate to enable separation, and allows for suitable formation of a favorable growth surface on the substrate from which a quality synthetic diamond can be grown. Therefore, the species is selected so as to allow for suitable implantation within the substrate without damaging the substrate. Small- to medium-sized species (having small- to medium-sized covalent radiuses) are generally preferred. Examples include atomic species such as helium, lithium, boron, carbon, oxygen, phosphorous, and sulfur. However, embodiments of the process can also involve large-sized species (having large-sized covalent radiuses). In such embodiments, other parameters affecting the implant of the species, such as species dose quantity and species energy level, are considered so as to limit the amount of damage to the substrate lattice upon implantation of the larger-sized species.

As mentioned, the extent of lattice damage to the implanted portion can be limited by the dose quantity of the species implanted, with dose being defined as the area density of atoms (atoms/cm²) which are implanted into the substrate. For example, if the species is implanted using a high dose, the species will generally cause more damage to the substrate upon implantation than if a species were implanted using a lower dose. As the species (of ionized atoms) travels through the substrate, the damage to the substrate lattice is generally maximized near the end of the species range into the substrate (generally referred to as “end of range damage”). In turn, the degree of damage at the end of range is a function of the total dose at that level. However, the ability to separate the grown diamond crystal from the seed is also a function of the total dose. At dose levels that are too low, there will be no separation, while at levels that are too high for a particular embodiment, there can be excessive damage and poor diamond growth. In currently preferred embodiments of this invention, the dose quantity is set in the range from about 1×10e⁴ atoms/cm² to about 1×10e²⁰ atoms/cm², and even more preferably, is set in the range from about 1×10e¹⁵ atoms/cm² to about 1×10e¹⁸ atoms/cm². When implanting species of large sizes, in order to limit lattice damage, it is generally preferable to choose a dose quantity on the lower end of the range. Conversely, when implanting species of small to medium sizes, any dose quantity within the range is generally suitable.

In addition, the extent of lattice damage to the diamond growth surface can be controlled by modifying the voltage of the electric field used in ion implantation. As one increases the voltage of the electric field, the energy of the species increases as well, ultimately resulting in a deeper implantation by the species into the substrate. In turn, the energy level can be selected for a specific species so as to implant a peak concentration of the species at about a certain implantation depth within the substrate (the end of range depth). This depth may range anywhere from about 500 angstroms to about 20,000 angstroms. Generally, the voltage energy is maintained at one level during implantation to generally attain one implanted layer. However, it is to be appreciated that the implant depth of the species can also be varied by varying voltage energy during the implantation process. Further, if the voltage energy is held at a certain number of levels for requisite amounts of time during implantation of a species, the species can be distributed in a similar number of implanted layers throughout the diamond. As such, each of these implanted layers, if sufficiently distributed across the implanted-upon diamond, could serve as surfaces at which the implanted-upon diamond can be separated.

While the end of range depth for the species can be limited by decreasing the species energy (e.g., so as to minimize substrate loss during separation), one ought not limit the energy too severely. In the method of this invention, Applicants have found that the depth of the implant plays a significant role, as the mechanical stability of the substrate is strongly influenced by the depth of the implant. As such, an implant that is too shallow (too low in energy) can result in damage at or beneath the diamond growth surface of the substrate, thus making the substrate unsuitable for subsequent processing (e.g., diamond growth thereon). Such damage can include blistering, delamination, and crystallographic defects. Consequently, it is preferable to provide enough energy to the species so as to not compromise the mechanical stability of the substrate, preferably at the diamond growth surface. In currently preferred embodiments of this invention, therefore, the energy level is set in the range from about 10 KeV to about 10,000 KeV, and even more preferably, is set in the range from about 50 KeV to about 500 KeV. When implanting species of large sizes, in order to limit lattice damage of the substrate, it is preferable to select the species energy on the higher end of this range. As such, the large size species are implanted further from the diamond growth surface, thereby attempting to isolate any lattice damage from the diamond growth surface. Conversely, when implanting species of small to medium sizes, the method provides more freedom in selecting the species energy.

One other parameter of the species that generally influences the inventive process is the species dose rate. The dose rate affects the temperature of the substrate during the implant. As such, if the dose rate is too high, the subsequent diamond growth on the substrate and/or overall separation from the substrate may be negatively affected. Conversely, if the dose rate is too low, unwanted graphitization of the zone of the implanted layer may occur. In currently preferred embodiments of this invention, the dose rate is set in the range from about 0.05 microamps/cm² to about 100 milliamps/cm², and even more preferably, is set in the range from about 0.1 microamps/cm² to about 500 microamps/cm².

Given the present description, those skilled in the art will appreciate the manner in which the end of range depth of the species can be determined, given specifics regarding the species implanted and the energy used. Such calculations are generally known as TRIM (Transport of Ions in Matter) calculations. See J. P. Biersack et al., A Monte Carlo Computer Program for the Transport of Energetic Ions in Amorphous Targets, Nucl. Instr. Meth., pp. 174:257 (1980), the teachings of which are incorporated herein by reference. See also generally J. F. Ziegler et al., In the Stopping and Range of Ions in Matter, Pergamon Press, N.Y., vol. 1 (1985)., the teachings of which are incorporated herein by reference. Table 1 lists the approximate end of range depths for various species at various energy levels, given a diamond seed being used as the substrate. Regardless of whether the diamond seed is HPHT, CVD, or natural diamond, the end of range depths for the species generally remain the same. As illustrated, as the energy level is increased for a species such as hydrogen, its end of range depth is also increased. Calculations were run at an energy level of about 200 keV for species including boron and carbon to demonstrate that as the atom diameter of the species increased, the corresponding end of range depth decreased. In addition, it should be noted that in order to achieve similar end of range depths (e.g., 1900 angstroms to 2000 angstroms), energy levels would have to be increased by a factor of four when using carbon as the implant species as opposed to hydrogen.

TABLE 1
Implant Depths as a Function of Atom Implanted
and Implant Energy

| | |
|---|---|
| Implanted | Implant Energy |

| Ion/atom | 50 keV | 100 keV | 200 keV | 1,000 keV |
|---|---|---|---|---|
| Hydrogen | 1900 Å | 3700 Å | 7200 Å | 63500 Å |
| Boron | | | 2800 Å | |
| Carbon | | | 2000 Å | |

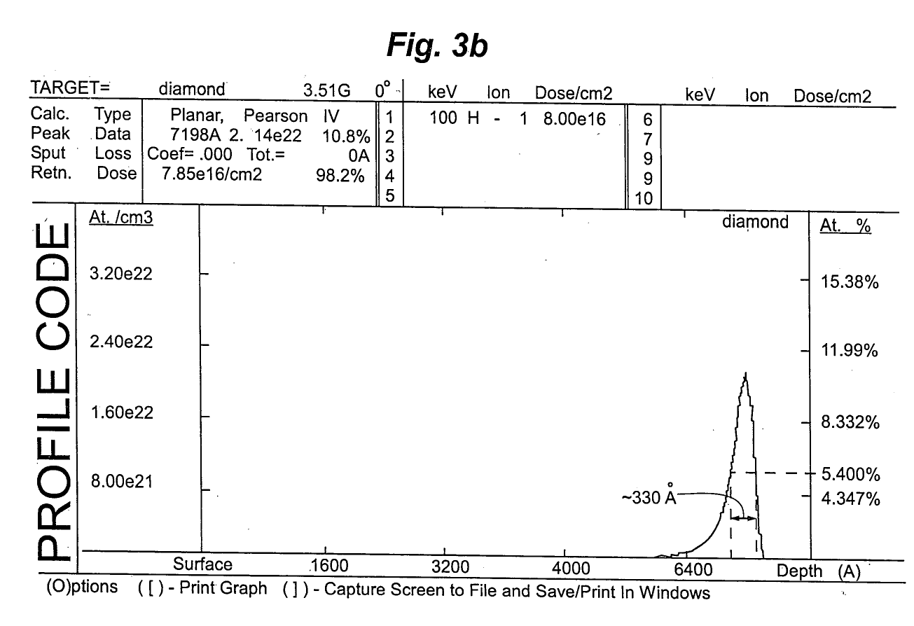

Graphs generally showing the information contained in Table 1 are also included as FIGS. 3a though 3e. The graphs illustrate implant profiles for these species, and involve the plotting of data computed from the TRIM calculations, with the species concentration being represented on the y-axis in atoms per cubic centimeter and the implantation depth of the species being represented on the x-axis in angstroms (A). Each graph typically shows high species concentration (represented by the curve) at and proximate to the end of range depth (represented by a general peak of the curve). Such curve represents the zone within the implanted layer of the substrate where the implanted ions generally come to rest following implantation. As illustrated, this zone generally lies below the substrate surface. The peak of the curve, generally indicating the end of range depth for the implanted species, is of particular importance because it corresponds with the depth proximate to where separation occurs. FIGS. 3a through 3c illustrate curves representing ion implantation of hydrogen at respective energy levels of 100 keV, 200 keV, and 1000 keV. FIGS. 3d and 3e illustrate curves representing ion implantation of boron and carbon respectively, at energy levels of 200 keV.

In reference to the graphs (3b, 3d, and 3e) illustrating the three species (hydrogen, boron, and carbon, respectively) implanted at 200 keV, the width of the depth profile (curve) becomes broader as the atom diameter of the species increases. To illustrate this, the run (width) of the curve is generally measured at points halfway up the rise of the curve. The run of the curve is measured at these locations to focus on the general slope of the curve and eliminate curve portions that deviate from this general slope of the curve. For hydrogen, the run is about 330 angstroms; for boron, the run is about 550 angstroms; and for carbon, the run is about 414 angstroms. As the curve run is extended in the cases involving boron and carbon, the concentration of the species at the end of range depth is generally reduced because concentrations of the species above and below the end of range depth are increased. As such, in the cases in which boron and carbon are selected as the species for ion implantation, the species is distributed more evenly along a wider portion (indicated by the run) of the substrate as opposed to the case involving hydrogen. In these cases involving boron and carbon, when separation is provided, the separation generally takes place across this wider portion of the substrate. With this, the potential increases for separation to not fully occur within the implanted substrate, or if occurring, generally causing a splintering of the separated surfaces.

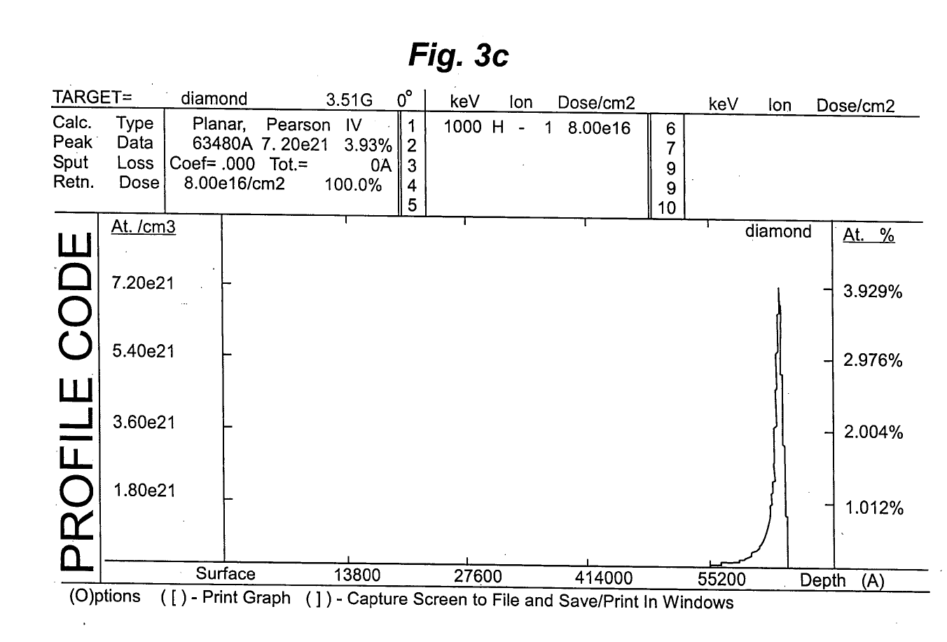

In certain embodiments, following the creation of a desirable implanted layer 18 within the substrate 12 via ion implantation, the substrate structure can be stored and utilized in the future to provide separation following growth of a synthetic diamond on the diamond growth surface of the substrate 12. In other certain embodiments, following such creation of a desirable implanted layer 18, a synthetic diamond 22 is grown on the substrate 12, as shown in FIG. 4. Synthetic diamond can be prepared in any suitable manner (e.g., by CVD or high pressure high temperature) and in any suitable form (e.g., mono- or polycrystalline). Preferred processes for growing monocrystalline CVD diamond are mentioned briefly herein and discussed in greater detail in U.S. Pat. No. 6,582,513, published U.S. patent application Ser. No. 10/328,987 (having publication No. U.S. Pat. No. 2003/0131787), and U.S. patent application Ser. No. 11/009,481, the entire disclosures of which are incorporated herein by reference.

In light of the above, it should be appreciated that the formed synthetic diamonds mentioned herein can be any of a vast variety. For example, the synthetic diamonds can be formed having one or more impurities and/or one or more carbon isotopes. It is often desirable to create synthetic diamonds having certain elements (e.g., impurities and/or carbon isotopes) to enable the diamonds to have enhanced and/or improved properties in a wide number of mechanical, electrical, optical, and quantum computing applications. Thus, if, for example, a boron doped synthetic diamond is desired for a specific application, the teachings herein (in combination with the appropriate diamond formation teaching) can be used to separate such a doped diamond from a substrate (e.g., a diamond seed). By combining the teachings of diamond formation processes with the separation techniques described herein, a plurality of methods would be available for producing synthetic diamonds having desired properties.

One such method involves starting with a diamond growth substrate (e.g., a diamond seed). The substrate is doped with one or more impurities as desired, for example, doped with boron atoms (e.g., via ion implantation), to achieve a desired doping level. Subsequently, atoms (e.g., hydrogen atoms) are ion implanted into the boron doped substrate in order to create a separation layer in the substrate. A synthetic diamond is subsequently formed on the boron doped diamond. Following the diamond formation, the teachings herein are used to separate not only the formed synthetic diamond but also a portion of the boron doped substrate (e.g., generally the substrate portion that is above the end of range depth of the separation layer).

Other methods can involve slight variations to the above method. For example, the same diamond growth substrate is used as in the above method; however, the substrate is not initially doped. Instead, the substrate is initially implanted with atoms (e.g., hydrogen atoms) to form a separation layer within the substrate. Subsequently, a synthetic diamond is formed on the substrate. This synthetic diamond is doped (e.g., via ion implantation) as it is formed. Following the synthetic diamond's formation, using the teachings herein, one can separate the doped synthetic diamond and also a portion of the substrate (e.g., generally the substrate portion that is above the end of range depth of the separation layer).

A further method may also use the same diamond growth substrate as mentioned in the previous methods; however, the substrate is not doped or implanted to create a separation layer. Instead, a synthetic diamond is formed on the substrate, and during such formation process, the synthetic diamond is doped (e.g., via ion implantation) and a separation layer is formed via ion implantation of atoms (e.g., hydrogen atoms) to form a separation layer within the synthetic diamond. Following the synthetic diamond's formation, the teachings herein are used to separate a desired portion of the doped synthetic diamond (e.g., generally the diamond portion which is above the end of range depth of the separation layer).

In describing these exemplary methods, it is not done with the intention of limiting the invention as such. On the contrary, the methods are demonstrated to introduce some fashions in which the separation techniques demonstrated herein can be used with different diamond formation processes to produce and separate a variety of synthetic diamonds. In turn, it is to be appreciated that these synthetic diamonds can be formed to exhibit any of a wide variety of desired properties (e.g., by achieving a certain warranted level of doping).

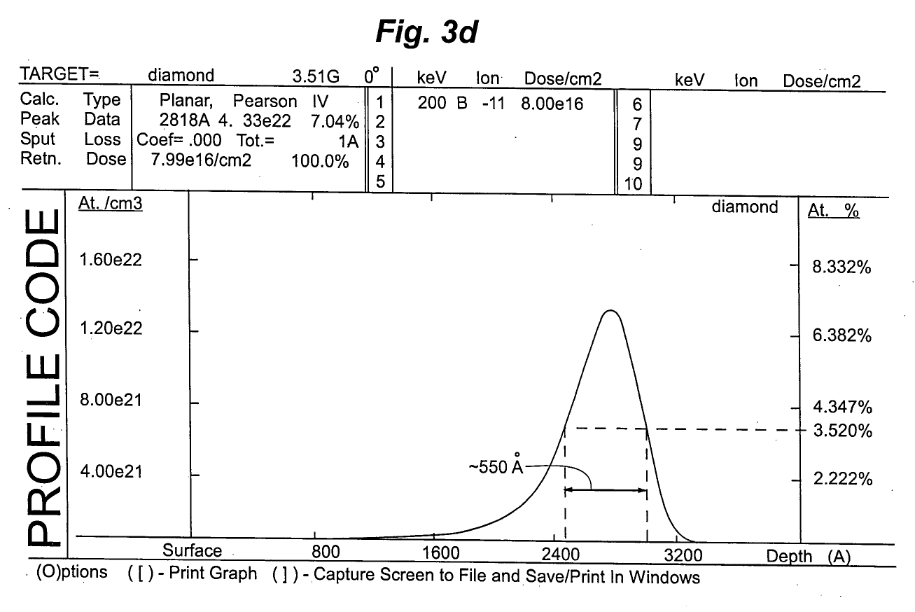

Generally, the synthetic diamond 22 is grown from all exposed surfaces of the substrate 12. In certain embodiments, once the growth process is concluded (e.g., the synthetic diamond 22 being grown to a desired thickness), side portions 24 of the synthetic diamond 22 are removed and discarded along dashed lines 26. Such side portions 24 grow laterally from the substrate 10 and are removed to generally leave the left-over synthetic diamond 22 with substantially the same base area as that of the implanted layer 18 of the substrate 12. Typically, the removal of such side portions 24 is provided using a laser cutter as described herein, so as to leave a configuration generally illustrated in FIG. 5. Subsequently, the remaining portion of the synthetic diamond 22 is separated from the substrate 12.

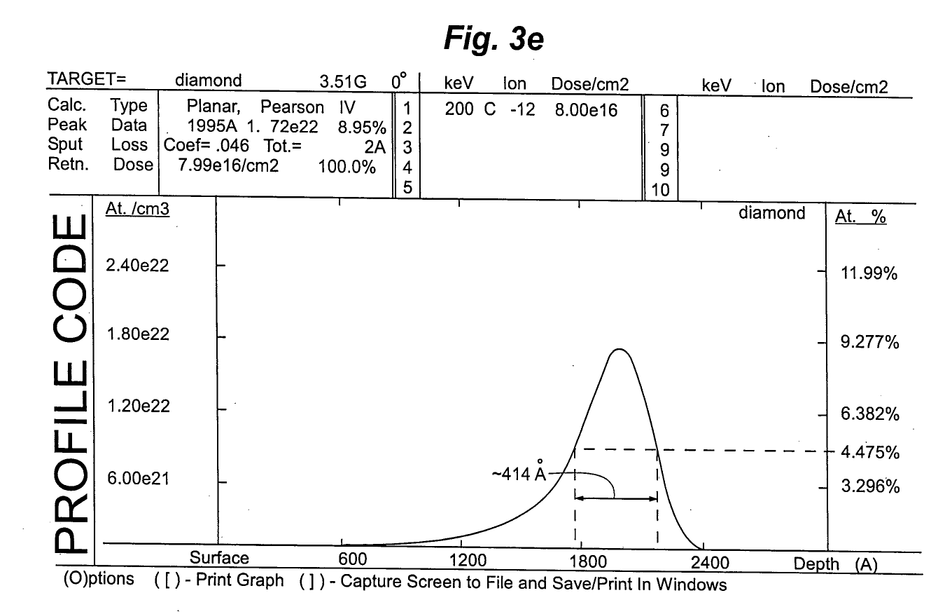

In certain embodiments, the synthetic diamond is removed from the implanted substrate (e.g., diamond seed implanted with hydrogen ions) by heating the diamond composition (i.e., diamond seed and synthetic diamond) to an elevated temperature in a non-oxidizing atmosphere. By using a species with a small- to medium-sized atom (e.g., hydrogen) as an implant, very low damage levels will be achieved in the implanted layer, which generally results in less strain at or beneath the diamond growth surface. Subsequently, higher quality synthetic diamond can be grown on the diamond growth surface and further separated from the substrate. With the species having a peak concentration at the end of range depth, separation typically occurs spontaneously across the entire end of range depth. Thus, a portion of the implanted layer of the substrate (formed to the synthetic diamond) is separated with the synthetic diamond. Heat treatments are provided on the diamond composition in the non-oxidizing atmospheres. Such treatments can be provided by any suitable method, including radiation, conduction, or convection sources, all generally known in the art. Generally, the temperature range of the heat treatments is preferably set in the range from about 1100° C. to about 1800° C. and, more preferably, about 1100° C. to about 1500° C. The combination of the appropriate atmosphere and the temperature levels provides an ideal environment to cause spontaneous separation of the synthetic diamond and the implanted layer portion from the remaining substrate. The composite of the synthetic diamond and the implanted layer portion is occasionally referred to herein as a synthetic diamond structure. The separation process can also generally be aided by the application of force, e.g., a lateral force on the side surface of the substrate at or near the end of range depth. As illustrated in FIGS. 5 and 6 and described herein, the separation generally occurs at and/or proximate to the end of range depth 20 within the substrate 12. As such, the separated synthetic diamond 22 takes with it a significant portion of the implanted layer 18 of the substrate 12, the synthetic diamond 22 and implanted substrate layer portion forming a synthetic diamond structure 28.

The method of separating synthetic diamond structures from substrates using the inventive process, as described and illustrated herein, permits such substrates to be re-used for growing further synthetic diamond structures, particularly since the amount of substrate that is lifted off the substrate with the grown diamond is typically minimal in comparison to the overall size of the substrate. In addition, the amount of synthetic diamond that is wasted is also minimized in contrast to many of the conventional separation methods involving cutting. However, following separation of the synthetic diamond structure, the remaining substrate generally is left with an implanted portion at and/or beneath an exposed surface. This implanted portion can generally be removed (e.g., by conventional polishing or cutting methods) so as to provide a clean substrate surface for further synthetic diamond growth.

Regarding synthetic polycrystalline diamond, such diamond generally needs to be initially grown (e.g., from a non-diamond substrate) to a certain base depth before acceptable diamond can start being grown. As such, the grown polycrystalline diamond develops its grain structure below the certain base depth and only forms a suitable grain structure when it is grown up to the certain base depth. Unfortunately, growing the polycrystalline diamond to this certain base depth is a lengthy process. With the inventive method, a polycrystalline diamond may be grown to this certain base depth and then subsequently be used as a seed for repeatedly growing polycrystalline diamond thereon. Thus, following each growth process, the grown synthetic polycrystalline diamond would be separated from the polycrystalline diamond seed, and the seed could be used again. As such, the time normally dedicated to growing the polycrystalline diamond to the certain base depth would be eliminated, and as such, diamond yield could be greatly increased.

As mentioned above, the dose rate of the implanted species generally affects the temperature of the substrate. Preferably, the dose rate, and in turn, the substrate temperature are selected in a manner that avoids the unintentional formation of a graphitic layer. This graphitic layer would generally include the zone within the substrate where the implanted ions come to rest following implantation. Optionally, and in the event formation of a graphitic layer is desired, one can either adjust the dose rate accordingly (e.g., lower the rate so that it drops out of the preferred range) or sufficiently cool the substrate during ion implantation. The separation method of this invention can be used in spite of the formation of such graphitic layer, typically permitting separation to occur at the end of range depth within the graphitic layer itself. In turn, a portion of the graphitic layer (as part of the substrate implanted layer) will itself be separated from the remaining substrate, either alone or in combination with diamond grown thereon.

In a particularly preferred embodiment, the method of this invention is used to prepare synthetic diamond structures for diamond applications requiring a prescribed amount of overall strain. See, for instance, Applicant's own U.S. patent application Ser. No. 10/328,987 (having publication No. US 2003/0131787), which describes the manner in which synthetic diamond layers can be formed to provide diamonds that are appropriately “tuned” by varying the strain associated with the different layers. For instance, strain can be introduced to a diamond by forming layers that are mismatched, with respect to their respective lattice structures. As such, the layers are deliberately strained in relationship to each other to achieve a desired purpose. Conversely, layers can be formed having matched lattice structures, thereby providing layers that will tend to coexist without undue strain. The layers can be made to have matched or mismatched lattices by the incorporation of impurities (e.g., boron, nitrogen, and phosphorous atoms) and/or isotopes (e.g., ¹³C carbon isotope) into the layers that are formed.

In the method of the current invention, the implanted layer of the substrate can be effectively lattice matched or mismatched to the grown synthetic diamond in a similar fashion, in order to provide a desired level of strain, and thereby tune the resulting structure. For instance, a species is typically implanted within a surface of the substrate before a synthetic diamond is formed on the substrate surface. Upon separation of the synthetic diamond structure (including the synthetic diamond and a portion of the implanted layer of the substrate), the separated diamond structure will generally have lattice strain, due to the likely lattice mismatch between the implanted layer portion and the synthetic diamond. Applicants describe the manner in which the species dose quantity can be manipulated to achieve a certain species concentration within the substrate prior to separation. Taken together, these features permit one to effectively “tune” the resultant synthetic diamond structure, so as to be suitably strained for use in a particular application in the industry. Such strained structures are in demand in the semiconductor and optical industries. In certain embodiments, therefore, when initially selecting the species for implantation, it is preferable to select a species (e.g., boron) that will correspond well to the ultimate diamond device or function. The selected species can be implanted within the substrate at an appropriate concentration level, after which one or more synthetic diamond layers can then be grown in a manner that provides a suitably tuned synthetic diamond structure that can be removed and used for any suitable purpose, such as in electrical, optical or other applications.

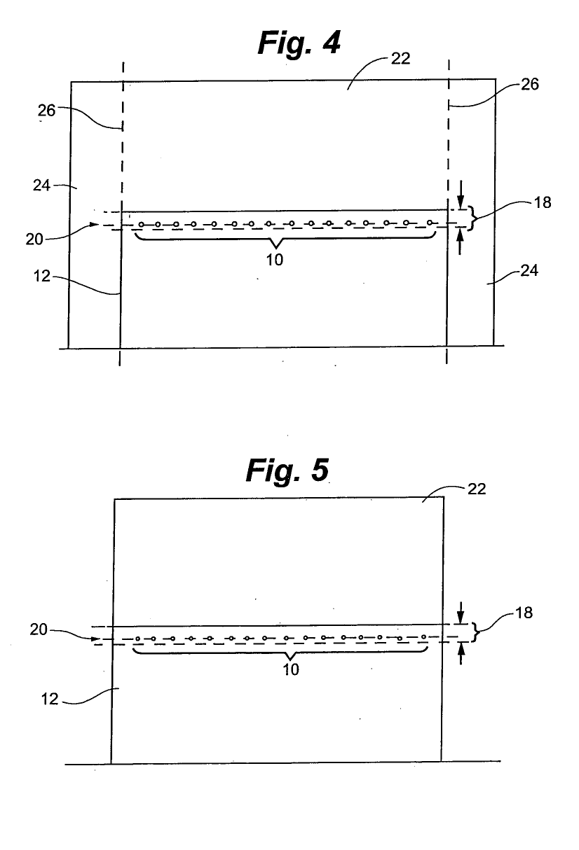

In an alternate embodiment, a substrate can be used having a shape other than the rectangular shape referenced herein. FIG. 7 illustrates one such substrate 30 generally of a shape of a frustum of pyramid. The substrate 30 has a generally rectangular midsection 32, with side portions 34 having upper surfaces that angle generally downwardly from upper corners 36 of the midsection 32. As should be appreciated, the substrate 30 illustrated in FIG. 7, like the substrate 12 introduced in FIG. 1, is exemplary and should not limit the invention. As mentioned herein, the substrate can be any shape, including shapes that have few if any angular limitations at all. For example, the substrate can have an outer surface having one or more portions that are non-linear, and in certain embodiments, the outer surface may be entirely non-linear so as to have a continuous curvature.

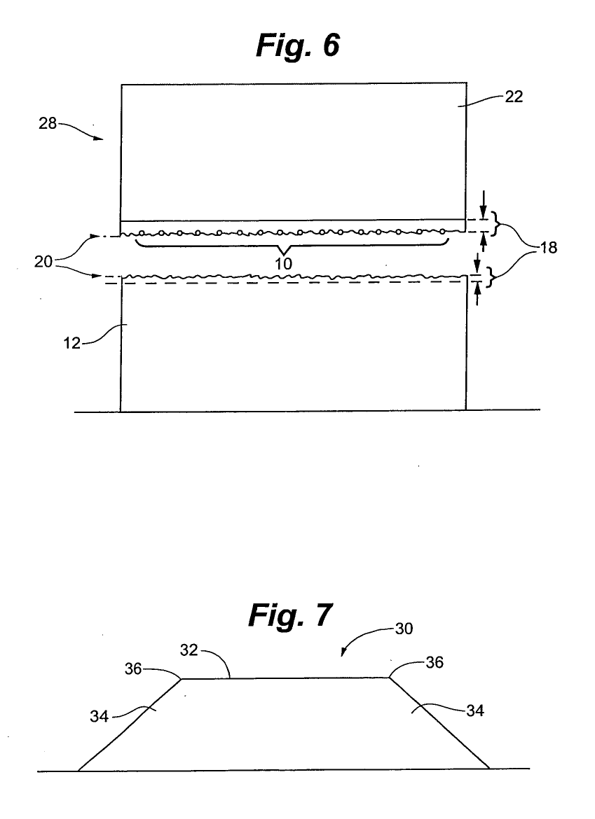

In using such substrate 30, an ion implantation process is performed in a similar manner to what has already been described herein. Following the implantation, the substrate 30, as represented in FIG. 8, will once again have a species 38 (of ionized atoms) implanted therein. However, unlike with the rectangular substrate 12 (FIGS. 1, 2, 4-6), the implantation occurring at the diamond growth surface of the substrate 30 involves the exposed surface of the midsection 32 as well as each of the side portions 34 of the substrate 30. The species 38 generally penetrates the outer surface of each of the midsection 32 and side portions 34 until reaching corresponding zones within the substrate 30. These zones are generally included within implanted layers 40, 42 for the midsection 32 and the side portions 34 respectively. The implanted layers 40, 42 generally extend from corresponding outer surfaces of the substrate 30 to the farthest penetration depth of the species 38 within the substrate 30. A peak concentration of the species 38 is at certain depths 44, 46 within the respective implanted layers 40, 42. These depths 44, 46 are generally known as the end of range depths. While the species 38 is only shown at the depths 44, 46 within each of the respective midsection 32 and side portions 34 of the substrate 30, it should be appreciated that this is done for simplicity. Following ion implantation, the species is generally distributed throughout the zones at and proximate to the end of range depths 44, 46. As shown, the implanted layers 40 and 42 respectively extend beneath the end of range depths 44 and 46. While the implanted layer 42 and end of range depth 46 for each of the side portions 34 are generally the same, the side portions can have upper surfaces with distinct slopes from each other, so that different implantation layers and different penetration depths are created for each side portion 34.

In comparing the implanted layers 40, 42 of this substrate 30 with the implanted layer 20 obtained after implanting on the rectangular substrate 12 (see FIG. 2), it can be seen that substrate 30 can be used to provide more efficient growth and subsequent separation surface, since implantation occurs at surfaces to the midsection 32 and the side portions 34. This extended lateral surface of the substrate 30, in turn, leads to a greater yield of synthetic diamond from the substrate 30. In addition, the end of range depths 44 and 46 within the respective implanted layers 40, 42 are generally dependent on the angle at which the species contacts the substrate 30. If the implanted surface is not normal (i.e., 90°) from this accelerated species 38, then the concentration and penetration of the implanted species 38 are generally reduced.

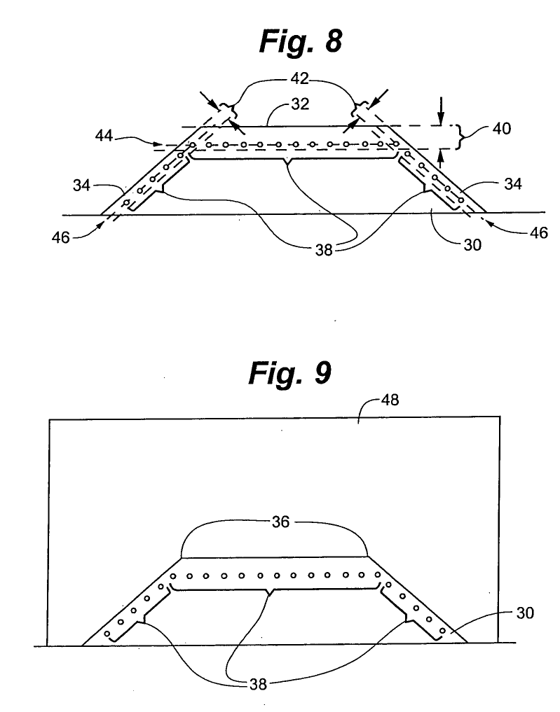

In certain embodiments, following the creation of a desirable implanted layers 40, 42 within the substrate 30 via ion implantation, a substrate structure is created that can be utilized in the future to provide separation following growth of a synthetic diamond on the diamond growth surface of the substrate 30. In other certain embodiments, following such creation of a desirable implanted layers 40, 42, a synthetic diamond 48 is grown on the substrate 12, as shown in FIG. 9. The synthetic diamond 48 is generally grown by any conventional manner mentioned herein, and grown from all exposed surfaces of the substrate 30. Once the growth process is concluded (e.g., the synthetic diamond 48 is grown to a desired thickness), the synthetic diamond 48 is generally ready for separation from the substrate 30. In contrast to the synthetic diamond 22 grown from the rectangular substrate 12 (FIG. 1), side portions of the synthetic diamond 48 do not initially have to be removed to facilitate separation. As such, separation using such alternate substrates 30 provides for a shortened method duration and has greater potential for increased diamond yield.

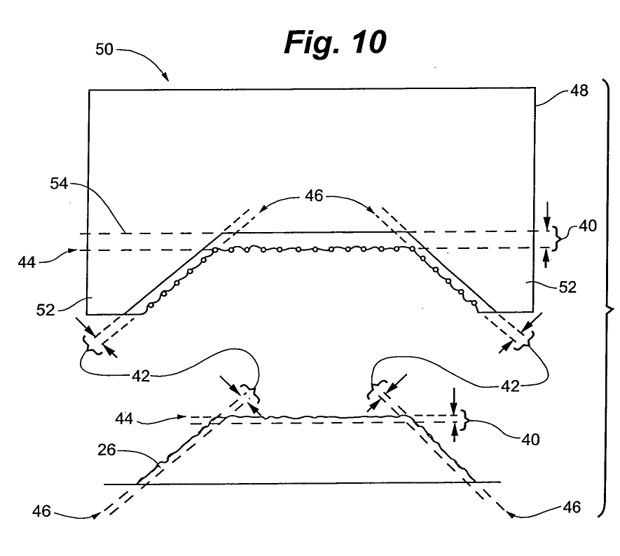

As illustrated in FIG. 10, the separation generally occurs at the end of range depths 44, 46 within the substrate 30. As such, the synthetic diamond 48 incorporates portions of the implanted layers 40, 42 of the substrate 30. As such, the separated synthetic diamond 48 and portions of the implanted layers 40, 42 form a synthetic diamond structure 50. The separated synthetic diamond structure 50 additionally includes “fang like” projections 52. In certain embodiments, these projections 52 can be removed by polishing or laser cutting so as to align them with the end of range depth 44 of the implanted layer portion 40. As such, the lower surface of the synthetic diamond structure 50 can be smoothed to provide an end product similar in shape to the previously described synthetic diamond structure 28 obtained from the rectangular substrate 12. Generally, such synthetic diamond structure shapes are more suitable for being used in a wide variety of diamond applications. Alternatively, if one wanted the synthetic diamond structure 50 to not include any of the implanted layer 40, the structure 50 can be cut across dashed line 54.

A surprising and additional benefit provided by the alternate embodiment is that the amount of diamond growth can be greatly increased through such manipulation of the substrate. As described herein, by generally altering the sides so that they downwardly slope away from the upper portion of the substrate, one can provide for additional implantation which facilitates increased diamond yield from the substrate. As such, it is not necessary to remove any of the grown diamond prior to its separation, which results in an unlimited potential for diamond yield per growth process. While this invention is generally applicable to all processes in which synthetic diamond is grown from a substrate, it is particularly applicable with regard to current processes that use large substrates, and in future processes that will use even larger substrates, in which sizes of grown diamonds would be very high, and the reduction of wasted grown diamond can lead to significant increases in yield.

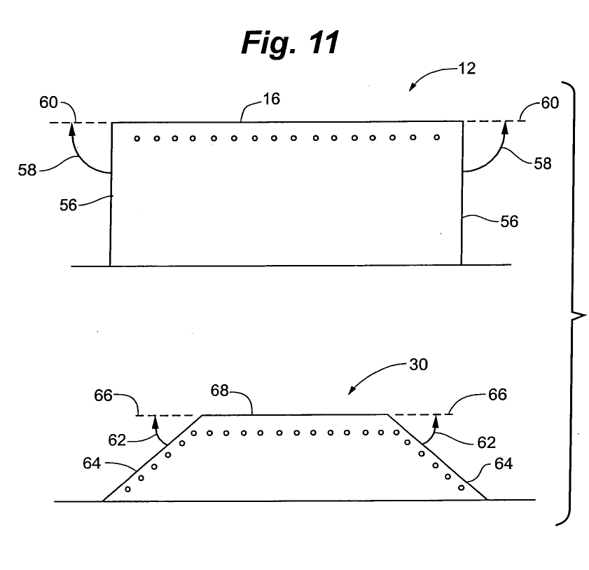

With regard to the rectangular substrate 12 (illustrated in FIGS. 1, 2 and 4 through 6) and the alternatively shaped substrate 30 (illustrated in FIGS. 7 through 10), it should be appreciated that ion implantation generally occurs at all upwardly exposed surfaces. Substrates 12, 30 are generally shown in FIG. 11 subsequent to ion implantation. The only surfaces of the two illustrated substrates 12, 30 exposed during the ion implantation, yet not implanted upon, are the side surfaces 56 of the rectangular substrate 12. An angle 58 formed between these side surfaces 56 of the rectangular substrate 12 and a line 60 extending horizontally from the upper surface 16 is generally about 90°. In contrast, an angle 62 formed between side surfaces 64 of the alternative substrate 30 and a line 66 extending horizontally from the upper surface 68 is generally about 45°.

Side surfaces 64 of the substrate 30 can be adjusted to slope at an even sharper downward orientation than shown, thereby further increasing angle 62, while still permitting sufficient implantation to occur. As angle 62 approaches 0°, however, the concentration of the species as well as the depth of penetration in the side surfaces 64 in turn gradually increases to the point at which they both are about the same depth and dose as in the midsection. Conversely, as angle 62 approaches 90°, the concentration as well as the depth of penetration of the species on the side surfaces 64 are gradually reduced, reaching levels of close to zero at 90°. The dose concentration is exemplified generally using the equation:
a₂=a₁ cos θ (1),
where a₂ is the dose concentration within the side surface portion in question, a₁ is the dose concentration on the upper surface of rectangular midsection, and θ is the angle between the side surface and horizontal line extending from the upper surface of the rectangular midsection (referred to as 62 in FIG. 11). The depth of penetration is exemplified generally using the equation:
b₂=b₁ cos θ (2),
where b₂ is the depth of penetration within the side surface portion in question, b₁ is the depth of penetration within the upper surface of rectangular midsection, and θ is the angle between the side surface and horizontal line extending from the upper surface of the rectangular midsection (referred to as 62 in FIG. 11). It is also contemplated that other surfaces of the substrate could be altered in maximizing the efficiency of the process as well.

While embodiments of the present invention have been described, it should be understood that various changes, adaptations, and modifications may be made therein without departing from the spirit of the invention.

1. A method of providing a synthetic diamond structure, the method comprising the steps of:
a) providing a diamond growth substrate having a diamond growth surface with a predetermined geometry;
b) employing ion implantation to deliver an atomic species into and beneath the diamond growth surface in order to form an implanted layer with a peak concentration of atoms at a predetermined depth beneath the diamond growth surface;
c) growing a synthetic diamond of one or more diamond layers upon the diamond growth surface in order to provide a composition comprising the grown synthetic diamond upon the diamond growth surface of the substrate; and
d) heating the composition in a non-oxidizing environment under suitable conditions to cause separation of a synthetic diamond structure that comprises the grown synthetic diamond together with the substrate to about the predetermined depth from the remaining substrate.

2. The method of claim 1, wherein the separating step comprises heating the composition to a temperature of between about 1100° C. to about 1800° C.

3. The method of claim 1, wherein the separating step comprises providing a non-oxidizing environment comprising a plasma selected from inert and non-oxygen-containing gases.

4. The method of claim 1, wherein the method is used to provide a synthetic diamond structure having strain between the implanted layer of the substrate and the synthetic diamond.

5. The method of claim 1, wherein the step of employing ion implantation comprises use of an atomic species from the group consisting of hydrogen, helium, lithium, boron, carbon, oxygen, phosphorous, and sulfur.

6. The method of claim 1, wherein the step of employing ion implantation comprises delivering the atomic species to the substrate surface at a dose quantity of between about 1×10e¹⁴ atoms/cm² to about 1×10e²⁰ atoms/cm².

7. The method of claim 1, wherein the step of employing ion implantation comprises delivering the atomic species at an energy level of between about 10 KeV to about 10,000 KeV.

8. The method of claim 1, wherein the step of employing ion implantation comprises delivering the atomic species at a single energy level.

9. The method of claim 1, wherein the step of employing ion implantation comprises delivering the atomic species at a dose rate of between about 0.05 microamps/cm² to about 100 milliamps/cm².

10. The method of claim 1, wherein the substrate comprises a diamond seed in the form of a frustum of pyramid geometry.

11. The method of claim 1, wherein the step of growing a synthetic diamond comprises growing monocystalline CVD diamond.

12. The method of claim 1, comprising the further step of removing the implanted substrate portion from the grown diamond.

13. The method of claim 1, comprising the further step of implanting one or more impurities into one or more of the diamond growth substrate and the synthetic diamond in order to form an implanted layer of one or more impurities within one or more of the diamond growth substrate and the synthetic diamond.

14. A synthetic diamond structure prepared according to the method of claim 1.

15. A synthetic diamond prepared according to the method of claim 12.

16. The method of claim 1, wherein the growing step results in one or more synthetic diamond portions extending beyond the exposed, implanted surface area of the substrate, and the method comprises the further step of removing the one or more portions in order to provide a base area of the synthetic diamond substantially similar to the exposed, implanted surface area of the substrate.

17. A method of providing a synthetic diamond structure, the method comprising the steps of:
a) providing a diamond growth substrate having a diamond growth surface, the substrate comprising a frustum of pyramid geometry;
b) employing ion implantation to deliver an atomic species into and beneath the diamond growth surface in order to form an implanted layer with a peak concentration of atoms at a predetermined depth beneath the diamond growth surface, the atomic species comprising hydrogen with dose quantity of between about 1×10¹⁴ atoms/cm² to about 1×10e²⁰ atoms/cm², energy level of between about 10 KeV to about 10,000 KeV, and dose rate of between about 0.05 microamps/cm² to about 100 milliamps/cm²;
c) growing a synthetic diamond of one or more diamond layers upon the diamond growth surface in order to provide a composition comprising the grown synthetic diamond upon the diamond growth surface of the substrate, the synthetic diamond comprising monocystalline CVD diamond; and
d) heating the composition to a temperature of between about 1100° C. to about 1800° C. in a non-oxidizing environment of plasma having an atmosphere selected from inert and non-oxygen-containing gases under suitable conditions to cause separation of a synthetic diamond structure that comprises the grown synthetic diamond together with the substrate to about the predetermined depth from the remaining substrate.

18. A method of providing a substrate structure for use in diamond synthesis, the method comprising the steps of:
a) providing a substrate having a surface with a predetermined geometry;
b) employing ion implantation to deliver an atomic species into and beneath the surface in order to form an implanted layer with a peak concentration of atoms at a predetermined depth beneath the diamond growth surface, the peak concentration of atoms used for causing separation of a substrate structure that comprises the substrate to about the predetermined depth from the remaining substrate when the substrate is heated in a non-oxidizing environment under suitable conditions.
